(19) United States
(12) Patent Application Publication
(10) Pub. No.: US 2013/0153881 A1
(43) Pub. Date: Jun. 20, 2013

(54) ORGANIC LIGHT-EMITTING DEVICES AND LIGHT SOURCE SYSTEMS

(71) Applicants: Naoya Tokoo, Mito (JP); Shingo Ishihara, Mito (JP); Sukekazu Aratani, Hitachiota (JP); Hirotaka Sakuma, Hitachinaka (JP)

(72) Inventors: Naoya Tokoo, Mito (JP); Shingo Ishihara, Mito (JP); Sukekazu Aratani, Hitachiota (JP); Hirotaka Sakuma, Hitachinaka (JP)

(73) Assignee: HITACHI, LTD., Tokyo (JP)

(21) Appl. No.: 13/818,646

(22) PCT Filed: Aug. 16, 2011
(86) PCT No.: PCT/JP2011/068577

§ 371 Date: Feb. 22, 2013

(30) Foreign Application Priority Data
Sep. 24, 2010 (JP) 2010-213002

(51) Int. Cl. H01L 51/50

(52) U.S. Cl. CPC H01L 51/5096
USPC 257/40; 257/79

(57) ABSTRACT

The present invention provides an organic light-emitting device including a first electrode (101), a second electrode (102), organic multi-layers (105, 115) in which the organic multi-layers (105, 115) is formed between the first electrode (101) and the second electrode (102) and has a hole blocking layer (16), an emission layer (15), and an electron blocking layer (14), and the emission layer 15 is interposed between the hole blocking layer (16) and the electron blocking layer (14), a first light-emitting dopant is added to the hole blocking layer (16), a second light-emitting dopant is added to the emission layer (15), a third light-emitting dopant is added to the electron blocking layer (14), and the first light-emitting dopant and the third light-emitting dopant trap carriers penetrating the emission layer.

According to the invention, the emission layer can emit light at high efficiency and deterioration of the emission layer can be suppressed.

### TECHNICAL FIELD

The present invention relates to an organic light-emitting device, and a light source system using such the organic light-emitting device.

### BACKGROUND ART

As an existent example, a Patent literature 1 discloses an organic light-emitting device with an aim of efficiently emitting light in a blue region of visible electromagnetic wave spectra. This organic light-emitting device includes a first hole transport layer over an anode, a second hole transport layer, over the first transport layer, doped with a phosphorescent material that emits light from a triplet energy state of an organic molecule, a first electron transport layer, over the second hole transport layer, doped with a phosphorescent material that emits light from a triplet energy state of an organic molecule, a second electron transport layer over the first electron transport layer, and a cathode over the second electron transport.

### PRIOR ART LITERATURE

### Patent Literature

[Patent Literature 1] JP-2009-147364-A

### SUMMARY OF THE INVENTION

### Problem to be Solved by the Invention

In the prior art, since no appropriate dopants are added to an electron blocking layer and a hole blocking layer formed on both sides of an emission layer, there was a problem that prevention of deterioration in the emission layer and emission at high efficiency are not compatible.

The present invention intends to suppress deterioration of the emission layer and emit light at high efficiency from the emission layer.

### Means for Solving the Problem

An organic light-emitting device according to the present invention has a configuration that organic multi-layers has a hole blocking layer, an emission layer, and an electron blocking layer, and the emission layer is interposed between the hole blocking layer and the electron blocking layer; wherein a first light-emitting dopant is added to the hole blocking layer, a second light-emitting dopant is added to the emission layer, a third light-emitting dopant is added to the electron blocking layer, and the first light-emitting dopant and the third light-emitting dopant trap carriers that inject to the emission layer.

### Effect of Invention

According to the present invention, the emission layer can emit light at high efficiency and deterioration of the emission layer can be suppressed.

### BRIEF DESCRIPTION OF THE DRAWINGS

FIG. 1 is a cross sectional view showing an embodiment of an organic light-emitting device.

FIG. 2 is a cross sectional view showing an embodiment of an organic light-emitting device.

FIG. 3 is a cross sectional view showing an embodiment of an organic light-emitting device.

FIG. 4 is a conceptional view of an energy level in an existent configuration.

FIG. 5 is a conceptional view of an energy level in an embodiment of the present invention.

FIG. 6 is a conceptional view of an energy level in an embodiment of the present invention.

FIG. 7 is a conceptional view of an energy level (state) in an embodiment of the present invention.

FIG. 8 is a graph showing a relation between a current density and a current efficiency in OLEDs 1 to 3.

### MODE FOR CARRYING OUT THE INVENTION

Organic light-emitting devices and a light source system using the organic light-emitting device according to the embodiment of the present invention will be described.

The organic light-emitting device comprises: a first electrode; a second electrode; organic multi-layers formed between the first electrode and the second electrode; the organic multi-layers having a hole blocking layer, an emission layer, and an electron blocking layer; and the emission layer being interposed between the hole blocking layer and the electron blocking layer; wherein a first light-emitting dopant is added to the hole blocking layer, a second light-emitting dopant is added to the emission layer, a third light-emitting dopant is added to the electron blocking layer, and the first light-emitting dopant and the third light-emitting dopant trap carriers that inject to the emission layer.

In the organic light-emitting device, an electron transport material is added to the hole blocking layer, and a hole transport material is added to the electron blocking layer, and the following relations (1) and (2) are satisfied when assuming the energy of the lowest occupied molecular orbital of the hole transport material as LUMO (EBL_host), the energy of the lowest occupied molecular orbital of the first light-emitting dopant as LUMO (EBL_dop), the energy of the highest occupied molecular orbital of the electron transport material as HOMO (HBL_host), and the energy of the highest occupied molecular orbital of the third light-emitting dopant as HOMO (HBL_dop):

LUMO(EBL_host)≦LUMO(EBL_dop) (1)

HOMO(HBL_host)≧HOMO(HBL_dop) (2)

In the organic light-emitting device, the following relations (3) and (4) are satisfied when assuming the lowest triplet energy state of the first light-emitting dopant as T_{1EBL-D}, the lowest triplet energy state of the second light-emitting dopant as T_{1EML-D}, and the lowest triplet energy state of the third light-emitting dopant as T_{1HBL-D}:

T_{1EML}_{_{—D}}≦T_{1EBL}_{_{—}}_{D} (3)

T_{1EML}_{_{—}}_{D}≦T_{1HBL}_{_{—}}_{D} (4)

In the organic light-emitting device, the following relation (5) is satisfied when assuming the hole mobility in the emission layer as μ_{h-EML} and the electron mobility in the emission layer as μ_{e-EML}:

0.7μₕ_{_{—}}_{EML}≧μₑ_{_{—}}_{EML}≧1.3μₕ_{_{—}}_{EML} (5)

In the organic light-emitting device, the following relation (6) and (7) are satisfied when assuming an energy barrier at the boundary between the hole blocking layer and the emission layer as φₕ and an energy barrier at the boundary between the emission layer and the electron blocking layer as φₑ:

Φₕ≦0.3eV (6)

Φₑ≦0.3eV (7)

In the organic light-emitting device, the emission color of the first light-emitting dopant, the emission color of the second light-emitting dopant, and the emission color of the third light-emitting dopant are identical.

In the organic light-emitting device, the following relations (8) and (9) are satisfied when assuming the dopant concentration of the first light-emitting dopant in the hole blocking layer as D₁, the dopant concentration of the second light-emitting dopant in the emission layer as D₂, and the dopant concentration of the third light-emitting dopant in the electron blocking layer as D₃:

D₁≦0.1D₂ (8)

D₃≦0.1D₂ (9)

In the organic light-emitting device, the first light-emitting dopant, the second light-emitting dopant, and the third light-emitting dopant are blue phosphorescent materials.

In the organic light-emitting device, the blue phosphorescent material is FIr6 or FIrpic.

The organic light-emitting device comprises: a first electrode; a second electrode; organic multi-layers formed between the first electrode and the second electrode; the organic multi-layers having a hole blocking layer, a first emission layer, a second emission layer, and an electron blocking layer; and the first emission layer and the second emission layer being stacked and interposed between the hole blocking layer and the electron blocking layer; wherein a first light-emitting dopant is added to the hole blocking layer, a second light-emitting dopant is added to the first emission layer, a third light-emitting dopant is added to the electron blocking layer, a fourth light-emitting dopant is added to the second emission layer, the first light-emitting dopant traps electrons that inject to the first emission layer, and the third light-emitting dopant traps holes that inject to the second emission layer.

In the organic light-emitting device, the first light-emitting dopant is formed of a material identical with that of the second light-emitting dopant or the fourth light-emitting dopant, and the third light-emitting dopant is formed of a material identical with that of the second light-emitting dopant or the fourth light-emitting dopant.

In the organic light-emitting device, a third emission layer is formed between the first emission layer and the second emission layer, and a fifth light-emitting dopant is added to the third emission layer, whereby white light is emitted.

The light source system includes the organic light-emitting device and a driving device.

The organic light-emitting device comprises: a first electrode; a second electrode; organic multi-layers; a charge generation layer; the organic multi-layers and the charge generation layer being stacked alternately between the first electrode and the second electrode; the first electrode and the second electrode being in contact with the organic multi-layers; the organic multi-layers having at least a hole blocking layer, an emission layer, and an electron blocking layer; and the emission layer being stacked in plurality and interposed between the hole blocking layer and the electron blocking layer; wherein a light-emitting dopant is added to the hole blocking layer, the emission layer, and the electron blocking layer, and the light-emitting dopant traps carriers that inject to the emission layer.

Description is to be made further in details with reference to the drawings, etc. The following description shows specific examples of the content of the present invention and the present invention is not restricted to such description and can be altered or modified variously by persons skilled in the art within the range of technical idea disclosed in the present specification. Throughout the drawing, for explaining the examples, components having identical functions carry the same reference signs for which duplicate descriptions are to be omitted. “Identical” and “equal” used in the present invention may include manufacturing variations.

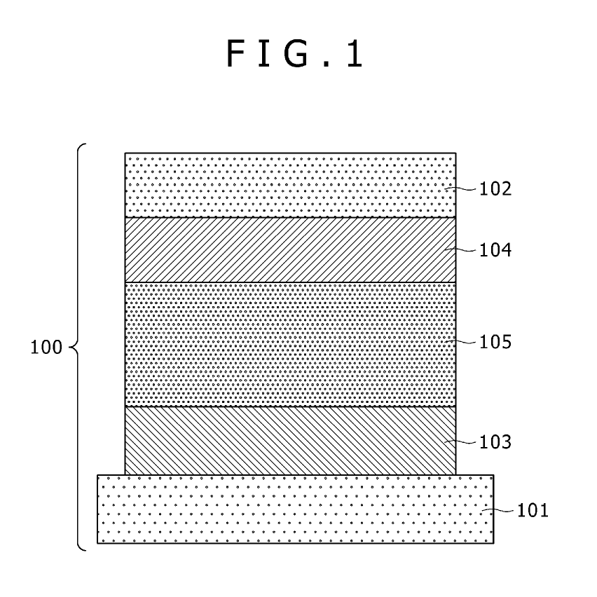

FIG. 1 is a cross sectional view of an embodiment of an organic light-emitting device.

An organic light-emitting device 100 comprises a first substrate 101, a second substrate 102, a first electrode 103, a second electrode 104, and first organic multi-layers 105. The first substrate 101, the first electrode 103, the first organic multi-layers 105, the second electrode 104, and the second substrate 102 are arranged in this order from the lower side of FIG. 1.

Assuming the first electrode 103 as a reflection electrode, that is, a cathode and the second electrode 104 as a transparent electrode, that is, an anode, the organic light-emitting device of FIG. 1 is a top emission type adapted to take out emission of the first organic multi-layers 105 on the side of the second electrode 104.

On the other hand, assuming the first electrode 103 as a transparent electrode, that is, an anode and the second electrode 104 as a reflection electrode, that is, a cathode, the organic light-emitting device of FIG. 1 is a bottom emission type adapted to take out emission of the first organic multi-layers 105 on the side of the first electrode 103.

Contact may be established between the first substrate 101 and the first electrode 103, between the first electrode 103 and the first organic multi-layers 105, and between the first organic multi-layers 105 and the second electrode 104, respectively. Since the first organic multi-layers 105 includes a red emission layer, a green emission layer, and a blue emission layer, white light is emitted from the first organic multi-layers 105. In order that the white light may be obtained, the first organic multi-layers may include a red emission layer and a green emission layer, the first organic multi-layers 105 may include a red emission layer and a blue emission layer, and the first organic multi-layers 105 may include a blue emission layer and a green emission layer. The first organic multi-layers 105 may be a mono-layer structure consisting of the emission layer, or a multi-layer structure containing one or more layers of an electron injection layer, an electron transport layer, a hole transport layer, and a hole injection layer.

A light source system is achieved by providing the organic light-emitting device of FIG. 1 with a driving device or the like. Examples of the light source system using the invention include, for example, illumination for domestic use, illumination in vehicles, backlight for liquid crystal display devices, etc., but they are not restrictive.

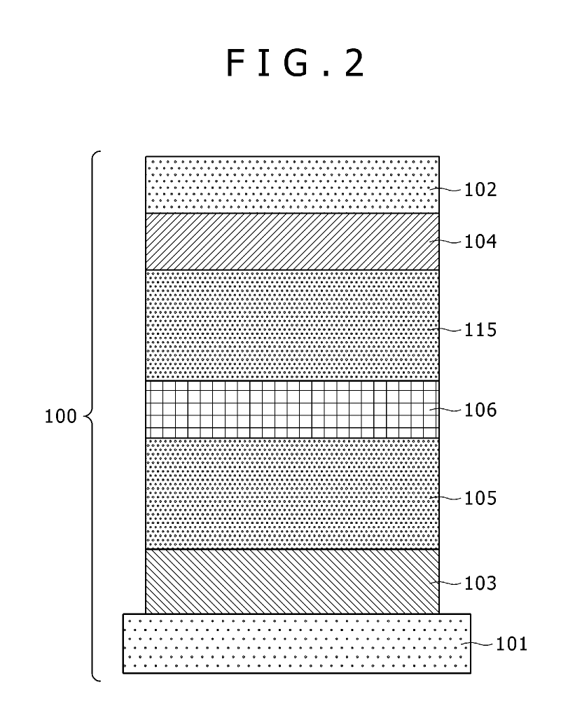

FIG. 2 is a cross sectional view of an embodiment of the organic light-emitting device.

The embodiment is different from that of FIG. 1 in that a first charge generation layer 106 is formed between a second electrode 104 and first organic multi-layers 105, and second organic multi-layers 115 is formed between the second electrode 104 and the first charge generation layer 106. FIG. 2 shows a so-called multi-photon emission (MPE) structure. A preferred specific example of the layer configuration of an organic EL device using the MPE structure of FIG. 2 is shown below but the invention is not restricted thereto. In the MPE structure, preferably, an emission layer for an emission color low in current efficiency is used for a mono-color and stacked emission layers are used for other emission colors. The MPE structure shows characteristics in which organic light-emitting devices using respective emission layers interposed between the electrodes are connected in series. Therefore, current is used entirely for mono-color emission in the mono-color emission layer of low efficiency, and the current is distributed to respective emission for two color emission layers and a white color spectrum can be obtained in two stages.
(1) First electrode/red green emission layer/charge generation layer/blue emission layer/second electrode
(2) First electrode/red blue emission layer/charge generation layer/green emission layer/second electrode
(3) First electrode/blue green emission layer/charge generation layer/red emission layer/second electrode

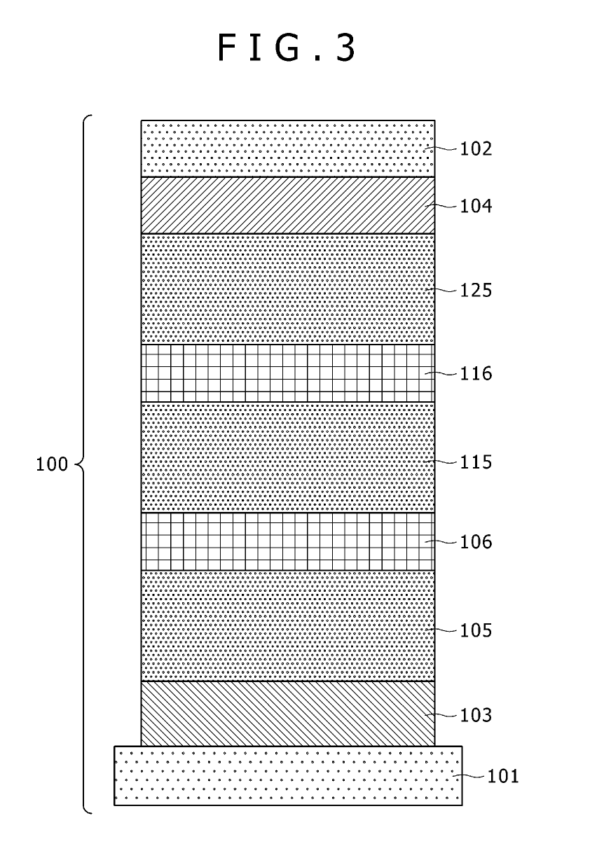

FIG. 3 is a cross sectional view in an embodiment of the organic light-emitting device.

The embodiment is different from that of FIG. 2 in that a second charge generation layer 116 is formed between a second electrode 104 and second organic multi-layers 115, and third organic multi-layers 125 is formed between the second electrode 104 and the second charge generation layer 116. FIG. 3 shows a so-called MPE structure. This is preferred in view of compatibility between the efficiency and the chromaticity. A preferred specific example of the layer configuration of the organic EL device using the MPE structure of FIG. 3 is shown below but the present invention is not restricted thereto. The MPE structure, preferably uses a red and green emission layer and mono-color blue emission layer. The red and green emission layer is formed by stacking red and green emission layers similar in physical property values such as a band gap of the organic material that forms the emission layer. This facilitates to attain high efficiency of the blue emission layer by separation from emission layers of other colors.
(1) First electrode/blue emission layer/charge generation layer/red green emission layer/charge generation layer/red green emission layer/second electrode
(2) First electrode/red green emission layer/charge generation layer/blue emission layer/charge generation layer/red green emission layer/second electrode
(3) First electrode/red green emission layer/charge generation layer/red green emission layer/charge generation layer/blue emission layer/second electrode.

The drawing shows a case in which three organic multi-layers and two charge generation layers are used but four or more organic multi-layers and three or more of charge generation layers may also be used. Also in this configuration, the organic multi-layers and the charge generation layers are stacked alternately between the first and second electrode and the first electrode and the second electrode are in contact with the organic multi-layers.

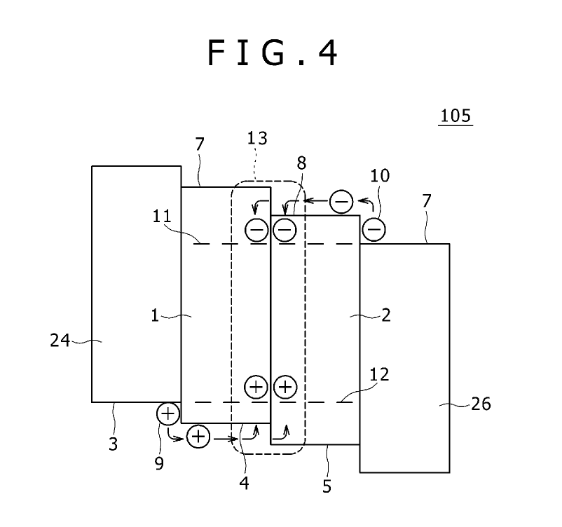

FIG. 4 shows a conceptional view of an energy level in an existent configuration of an organic light-emitting device.

In FIG. 4, a first organic multi-layers 105 comprises a hole transport layer 24, an emission layer 1, an emission layer 2, and an electron transport layer 26. The emission layer 1 contains a host material and a light-emitting dopant. The emission layer 2 contains a host material and a light-emitting dopant. When, in the light-emitting dopant of the emission layer 1 and the light-emitting dopant of the emission layer 2, a voltage is applied across electrodes of the organic light-emitting device formed of an identical material, electrons 10 and holes 9 are injected into the first organic multi-layers 105.

In the conceptional view of the energy level of FIG. 4, relation between respective layers is described below but this is not restrictive.

Usually, the ground state of an organic molecule is referred to as an HOMO (Highest Occupied Molecular Orbital) level and the state of excitation of the organic molecule is referred to as an LUMO (Lowest Unoccupied Molecular Orbital) level. In the present specification, HOMO means HOMO energy and LUMO means LUMO energy.

The HOMO energy is measured by a photoelectron spectroscopy. Further, the LUMO energy is measured by inverse photoelectron spectroscopy. Alternatively, the LUMO energy is calculated by adding the HOMO energy and the band-gap energy estimated from an absorption spectrum.

It is to be noted that HOMO is an abbreviation for the Highest Occupied Molecular Orbital and LUMO is an abbreviation for the Lowest Unoccupied Molecular Orbital.

In the drawing, the highest occupied molecular orbital 3 in the hole transport layer 24 is shallower than the highest occupied molecular orbital 4 of the host material in the emission layer 1. The highest occupied molecular orbital 4 is shallower than the highest occupied molecular orbital 5 of the host material in the emission layer 2. The lowest unoccupied molecular orbital 5 of the host material in the emission layer 2 is deeper than the lowest unoccupied molecular orbital 6 in the electron transport 26. The lowest unoccupied molecular orbital 7 of the host material in the emission layer 1 is shallower than the lowest unoccupied molecular orbital 8 of the host material in the emission layer 2. The lowest unoccupied molecular orbital 11 of the light-emitting dopant of the emission layer 1 (emission layer 2) is deeper than the lowest unoccupied molecular orbital 7 of the host material in the emission layer 1 and the lowest unoccupied molecular orbital 8 of the host material in the emission layer 2. The highest occupied molecular orbital 12 of the light-emitting dopant in the emission layer 1 (emission layer 2) is shallower than the highest occupied molecular orbital 4 of the host material in the emission layer 1 and the highest occupied molecular orbital 5 of the host material in the emission layer 2.

Holes 9 are blocked by an energy barrier present at the boundary between the emission layer 1 and the emission layer 2. In particular, as the current density increases, holes penetrating from the emission layer 1 to the emission layer 2 increase more. In the same manner, electrons 10 are also blocked by an energy barrier present at the boundary between the emission layer 1 and the emission layer 2. In particular, as the current density increases, number of electrons penetrating from the emission layer 2 to the emission layer 1 increases more. However, since the existent configuration shown in FIG. 1 is formed as a double emission layer, carriers penetrating one of the emission layers are trapped at the light-emitting dopant level of the other of the emission layers and contribute to emission by recombination. That is, holes penetrating the emission layer 1 are trapped at the light-emitting dopant level of the emission layer 2. Electrons penetrating the emission layer 2 are trapped at the light-emitting dopant level of the emission layer 1. Accordingly, a recombination region 13 (region where holes and electrons are recombined) has an extension around the vicinity of the boundary between the emission layer 1 and the emission layer 2, thereby increasing the emission efficiency. However, since, in the existent configuration, the recombination density increases and the excitation state is localized near the boundary between the emission layer 1 and the emission layer 2, there is a problem with material deterioration near the boundary between the emission layer 1 and the emission layer 2. The problem with the deterioration of the material is not restricted only to a case where the light-emitting dopant in the emission layer 1 and the light-emitting dopant in the emission layer 2 are of an identical material or an identical emission color.

On the other hand, an embodiment of the present invention intends to suppress deterioration of the material by decreasing the concentration of the excited state.

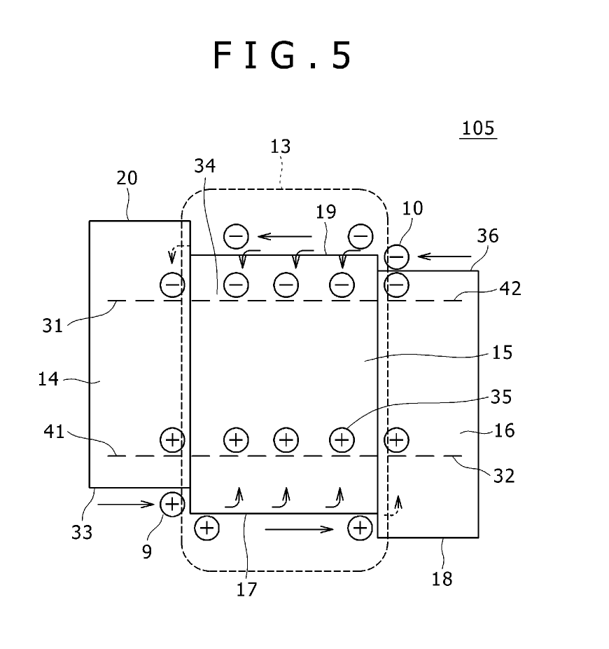

FIG. 5 shows a conceptional view of an energy level in an organic light-emitting device in the embodiment according to the present invention.

Referring to FIG. 5, a first organic multi-layers 105 comprises an electron blocking layer 14, an emission layer 15, and a hole blocking layer 16. A hole transporting material and a first light-emitting dopant are added to the electron blocking layer 14. A host material and a second light-emitting dopant are added to the emission layer 15. An electron transport material and a third light-emitting dopant are added to the hole blocking layer 16. An electron transport material and a third light-emitting dopant are added to the hole blocking layer 16. The hole blocking layer 16 is in contact with the emission layer 15, and the electron blocking layer 14 is in contact with the emission layer 15 on a side opposite to the side where the emission layer 15 is in contact with the hole blocking layer 16.

In the conceptional view of the energy level of FIG. 5, relation between respective layers will be described but this not restrictive.

The highest occupied molecular orbital 33 of the hole transport material is shallower than the highest occupied molecular orbital 17 of the host material in the emission layer 15. The highest occupied molecular orbital 17 of the host material in the emission layer 15 is shallower than the highest occupied molecular orbital 18 of the electron transport material. The lowest unoccupied molecular orbital 20 of the hole transport material is shallower than the lowest unoccupied molecular orbital 19 of the host material in the emission layer 15. The lowest unoccupied molecular orbital 19 of the host material in the emission layer 15 is shallower than the lowest unoccupied molecular orbital 20 of the electron transport material. The lowest unoccupied molecular orbital 31 of the first light-emitting dopant is deeper than the lowest unoccupied molecular orbital 19 of the host material in the emission layer 15. The highest occupied molecular orbital 41 of the first light-emitting dopant is shallower than the highest occupied molecular orbital 17 of the host material in the emission layer 15. The lowest unoccupied molecular orbital 34 of the second light-emitting dopant is deeper than the lowest unoccupied molecular orbital 19 of the host material in the emission layer 15. The highest occupied molecular orbital 35 of the second light-emitting dopant is shallower than the highest occupied molecular orbital 17 of the host material in the emission layer 15. The lowest unoccupied molecular orbital 42 of the third light-emitting dopant is deeper than the lowest unoccupied molecular orbital 19 of the host material in the emission layer 15. The highest occupied molecular orbital 32 of the third light-emitting dopant is shallower than the highest occupied molecular orbital 17 of the host material in the emission layer 15.

The first light-emitting dopant and the third light-emitting dopant trap carriers penetrating from the emission layer 15. As one of specific examples, when assuming the energy of the lowest unoccupied molecular orbital 20 of the hole transport material as LUMO (EBL_host), the energy of the lowest unoccupied molecular orbital 31 of the first light-emitting dopant as LUMO (EBL_dop), the energy of the highest occupied molecular orbital 18 of the electron transport material as HOMO (HBL_host), and the energy of the highest occupied molecular orbital 32 of the third light-emitting dopant as HOMO (HBL_dop), the relations of the following (formula 1) and (formula 2) are satisfied. Accordingly, the first light-emitting dopant and the third light-emitting dopant trap the carriers (holes or electrons) penetrating from the emission layer 15. Since carriers penetrating the emission layer 15 are trapped at the first light-emitting dopant or the third light-emitting dopant so that recombination occurs and light is emitted, lowering in efficiency can be suppressed.

LUMO(EBL_host)≦LUMO(EBL_dop) (Formula 1)

HOMO(HBL_host)≧HOMO(HBL_dop) (Formula 2)

Then, when assuming the hole mobility in the emission layer 15 as μ_{h-EML}, and the electron mobility in the emission layer 15 as μ_{e-EML}, the following (formula 3) is satisfied. Since localization of the excited state can be prevented in the emission layer 15, deterioration of the material can be decreased. The mobility is measured by a TOF method or an IS method. The TOF method is a method of generating sheet-like charges by a light pulse on the side of one electrode, sweeping them by an electric field on the opposite side, measuring the running time based on a transient current waveform and determining the mobility by utilizing an average electric field. The IS method is a method of applying a minute sinusoidal wave voltage signal to a device, and obtaining an impedance spectrum as a function of a frequency of the applied voltage signal based on the amplitude and the phase of a response current signal thereby calculating a running time, that is, a mobility.

0.7μₕ_{_{—}}_{EML}≧μₑ_{_{—}}_{EML}≧1.3μₕ_{_{—}}_{EML} (Formula 3)

When μ_{h-EML}=μ_{e-EML}, recombined carriers are at the maximum at the intermediate position in the direction of the thickness of the emission layer 15. When 0.7μ_{h-EML}=μ_{e-EML}, recombined carriers are at the maximum at a position displaced by about ¼ of the thickness of the emission layer 15 from the intermediate position in the direction of the thickness of the emission layer 15 to the cathode. When μ_{h-EML}=1.3μ_{e-EML}, recombined carriers are at the maximum at a position displaced by about ¼ of the thickness of the emission layer 15 from the intermediate position in the direction of the thickness of the emission layer 15 to the anode. Generally, the re-combination constant of the organic material used for the dopant is as small as the Langevin constant and recombination is weak. Accordingly, the recombination region 13 extends in the emission layer about a position where the recombination is at the maximum.

It is preferred that the second light-emitting dopant and the third light-emitting dopant be formed of an identical material (those having identical main skeleton, identical substituent or substituent of identical type). Further, assuming the wavelength where the intensity of the emission spectrum of the third light-emitting dopant is at the maximum as (λ₃) and the wavelength where the intensity of the emission spectrum of the second light-emitting dopant at the maximum as (λ₂), it is preferred that λ₃ be smaller than λ₂ and that the area of an emission spectrum component in a region of a wavelength longer than λ₃ be smaller than the area of an emission spectrum component in a region of a wavelength longer than λ₂. Further, it is preferred that the emission color of the second light-emitting dopant and the emission color of the third light-emitting dopant be equal (identical). In order that the emission colors are equal, it may suffice that the wavelength where the intensity of the emission spectrum of each of the respective light-emitting dopants is at the maximum is in a region of an identical color and it is preferred that the wavelengths where the intensity of the emission spectrum of each of the respective light-emitting dopants is at the maximum be equal. This can suppress lowering of the color purity of the emission spectrum.

When assuming the lowest triplet energy state of the third light-emitting dopant as T_{1HBL-D}, and the lowest triplet energy state of the second light-emitting dopant as T_{1EML-D}, the following (formula 4) is satisfied. Thus energy shift from the second light-emitting dopant to the third light-emitting dopant can be prevented and light is emitted in the emission layer 15. Accordingly, since the efficiency is improved, deterioration of the material can be decreased. Deterioration of the material can be decreased when the difference between T_{1EML-D}, and T_{1HBL-D} is 0.1 to 1.0 eV in formula 4, preferably, the different between T_{1EML-D} and T_{1HBL-D} is 0.3 to 0.5 eV. The lowest triplet energy state is measured by obtaining phosphorescence spectrum with a spectrophotometer and using the rising wavelength thereof. When difference between T_{1EML-D} and T_{1HBL-D} is 0 to 1.0 eV, the relation may be: T_{1EML-D}≧T_{1HBL-D}.

T_{1EML}_{_{—}}_{D}≦T_{1HBL}_{_{—}}_{D} (Formula 4)

It is preferred that the material for the first light-emitting dopant and that for the second light-emitting dopant be identical. Further, assuming the wavelength where the intensity of the emission spectrum of the first light-emitting dopant is at the maximum as (λ₁) and a wavelength where the intensity of the emission spectrum of the second light-emitting dopant is at the maximum as (λ₂), it is preferred that λ₁ be smaller than λ₂ and that the area of the emission spectrum component in a region of a wavelength longer than λ₁ be smaller than the area of the emission spectrum region in a wavelength region longer than λ₂. Further, it is preferred that the emission color of the second light-emitting dopant and the emission color of the first light-emitting dopant be equal. This can suppress lowering of the color purity of the light emission spectrum.

Assuming the lowest triplet energy state of the first light-emitting dopant as T_{1EBL-D}, the following (formula 5) is satisfied. Thus energy shift from the second light-emitting dopant to the first light-emitting dopant can be prevented. Accordingly, since the efficiency is improved, deterioration of the material can be reduced. Further, deterioration of the material can be decreased when the difference between T_{1EML-D} and T_{1EBL-D} in the following (formula 5) is 0.1 to 0.2 eV and, preferably, the difference between T_{1EML-D} and T_{1EBL-D} is 0.3 to 0.5 eV. So long as the difference between T_{1EML-D} and T_{1EBL-D} is from 0 to 0.2 eV, the relation may be T_{1EML-D}≧T_{1EBL-D}.

T_{1EML}_{_{—}}_{D}≦T_{1EBL}_{_{—}}_{D} (Formula 5)

When the blue phosphorescent material is used, since an internal quantum efficiency is lowered, that is, the roll off becomes significant in a region where the current density is relatively high, it is preferred that the first light-emitting dopant, the second light-emitting dopant, and the third light-emitting dopant be formed of blue phosphorescent materials.

As a combination of the electron blocking layer 14, the emission layer 15, and the hole blocking layer 16, preferably, the hole transport material for the electron blocking layer 14 is TAPC, the first dopant is FIr6, the host material for the emission layer 15 is UGH2, the second dopant is FIr6, the electron transport material for the hole blocking layer 16 is 3TPYMB, and the third dopant is FIr6, from the view point of the injection property, the transport property and the confinement of carriers in the emission layer 15.

Further, when assuming the energy barrier at the boundary between the electron blocking layer 14 and the emission layer 15 as φₑ and the energy barrier at the boundary between the emission layer 15 and the hole blocking layer 16 as φₕ, the followings (formula 6) and (formula 7) are satisfied. Since hole injection properties of from the electron blocking layer 14 to the emission layer 15 and electron injection properties of from the hole blocking layer 16 to the emission layer 15 are improved and high efficiency is provided, deterioration of the material can be reduced. Symbol φₑ is a value obtained by subtracting the energy of the highest occupied molecular orbital 33 of the hole transport material from the energy of the highest occupied molecular orbital 17 of the host material in the emission layer 15. The method of measuring HOMO for each of the materials is as has been described above. Further, symbol φₕ is a value obtained by subtracting the energy of the lowest unoccupied molecular orbital 19 of the emission layer 15 from the energy of the lowest unoccupied molecular orbital 36 of the electron transport material. The method of measuring LUMO for each of the materials is as has been described above.

Φₕ≦0.3eV (Formula 6)

Φₑ≦0.3eV (Formula 7))

It is preferred that the wavelength (λ₁) where the intensity of the emission spectrum of the first light-emitting dopant is at the maximum, the wavelength (λ₂) where the intensity of the emission spectrum of the second light-emitting dopant is at the maximum, and the wavelength (λ₃) where the intensity of the emission spectrum of the third light-emitting dopant is at the maximum be equal. Further, it is preferred that λ₁ and λ₃ be smaller than λ₂ and that the area of the emission spectrum component in a region of a wavelength longer than λ₁ and λ₃ be smaller than the area of the emission spectrum component in a region of a wavelength longer than λ₂. This can suppress the lowering of color purity of the emission spectrum.

When assuming the dopant concentration of the first light-emitting dopant in the electron blocking layer 14 as D₁, the dopant concentration of the second light-emitting dopant in the emission layer 15 as D₂, and the dopant concentration of the third light-emitting dopant in the hole blocking layer 16 as D₃, the relations of the following (formula 8) and (formula 9) are satisfied. Thus the emission intensity in the electron blocking layer 14 and the hole blocking layer 16 decrease. Generally, since the efficiency of the emission of the electron blocking layer 14 and the hole blocking layer 16 is lower compared with that of the emission layer 15, emission efficiency increase when the relations of the following (formula 8) and (formula 9) are satisfied. Since the emission by the second light-emitting dopant in the emission layer 15 is predominant, the effect is provided if the dopant concentration of D₁ and D₃ is about 1%. According to the conditions of the following (formula 8) and (formula 9), as the dopant concentration D₁ and D₃ increase, the emission intensity in the electron blocking layer 14 or the hole blocking layer 16 increases and the emission efficiency lowers.

D₁≦0.1D₂ (Formula 8)

D₃≦0.1D₂ (Formula 9)

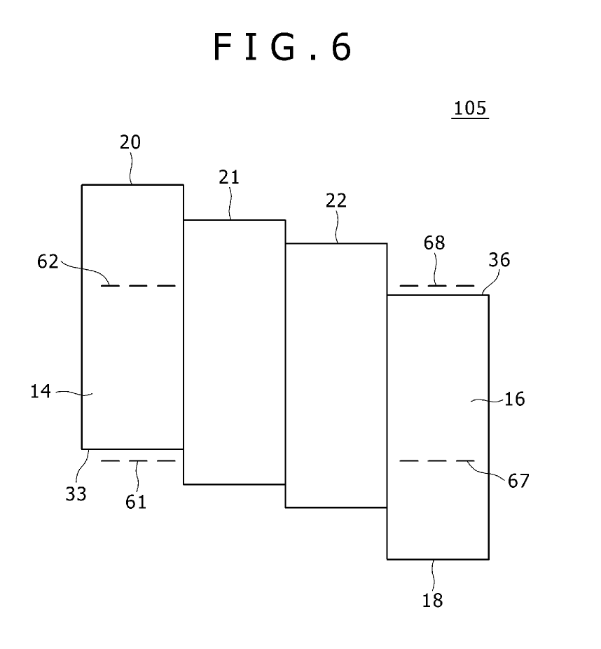

FIG. 6 shows a conceptional view of an energy level in an organic light-emitting device.

Also in the configuration in which two emission layers are stacked as shown in FIG. 6, localization of the excited state can be reduced. In FIG. 6, a first organic multi-layers 105 comprises an electron blocking layer 14, a first emission layer 21, a second emission layer 22, and a hole blocking layer 16. In the first emission layer 21, a second light-emitting dopant is added to a host material. In the second emission layer 22, a fourth light-emitting dopant is added to a host material. The electron blocking layer 14 is in contact with the first emission layer 21 on the side where the second emission layer 22 is not present, and the hole blocking layer 16 is in contact with the second emission layer 22 on the side where the first emission layer 21 is not present.

Referring to FIG. 6, a wavelength where the emission intensity of the second light-emitting dopant is at the maximum may be different from a wavelength where the emission intensity of the fourth light-emitting dopant is at the maximum. A color for the wavelength where the emission intensity of the second light-emitting dopant is at the maximum may be different from that for the wavelength where the emission intensity of the fourth light-emitting dopant is at the maximum. For example, in FIG. 2, white light emission can be achieved by adopting an MPE structure in which the emission color of the second light-emitting dopant is red and the emission color of the fourth light-emitting dopant is green in the first organic multi-layers 105, and the second organic multi-layers 115 is organic multi-layers containing a blue emission layer.

Preferably, the first light-emitting dopant and the third light-emitting dopant are formed of a material or have an emission color identical with that of the second light-emitting dopant or the fourth light-emitting dopant. In FIG. 6, the first light-emitting dopant is formed of a material identical with that of the fourth light-emitting dopant, and the third light-emitting dopant is formed of a material identical with that of the fourth light-emitting dopant.

Since, in the first emission layer 21, the lowest unoccupied molecular orbital 62 of the first light-emitting dopant is shallower than the lowest unoccupied molecular orbital 20 of the hole transport material, electrons penetrating the first emission layer 21 are trapped at the first light-emitting dopant, so that recombination occurs and light is emitted. Further, holes penetrating the first emission layer 21 are trapped at the fourth light-emitting dopant in the second emission layer 22, so that recombination occurs and light is emitted. Then, since, in the second emission layer 22, the highest occupied molecular orbital 67 of the third light-emitting dopant is shallower than the highest occupied molecular orbital 18 of the electron transport material, holes penetrating the second emission layer 22 are trapped at the third light-emitting dopant in the hole blocking layer 16, so that recombination occurs and light is emitted. Further, electrons penetrating the second emission layer 22 are trapped at the second light-emitting dopant in the first emission layer 21, so that recombination occurs and light is emitted. In this manner, light is emitted in the first emission layer 21, the second emission layer 22, the electron blocking layer 14, or the hole blocking layer 16, thereby achieving high efficiency light emission.

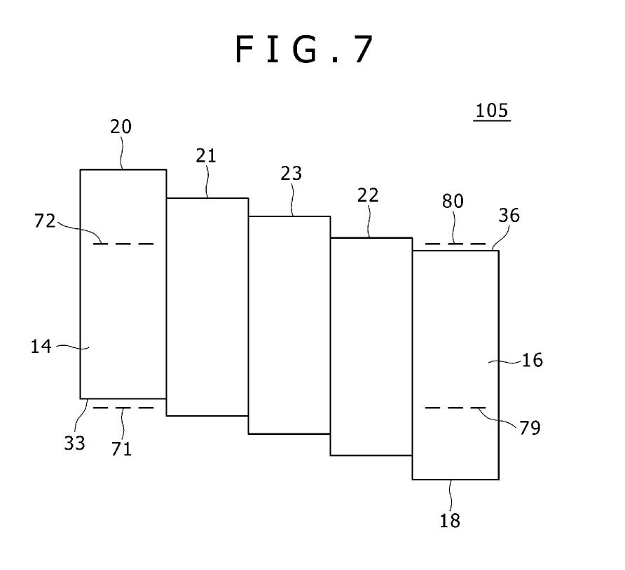

In the configuration of FIG. 6, since the highest occupied molecular orbital 61 of the first light-emitting dopant is deeper than the highest occupied molecular orbital 33 of the hole transport material, lowering of the hole transportability in the electron blocking layer 14 can be suppressed. Further, since the lowest unoccupied molecular orbital 68 of the third light-emitting dopant is shallower than the lowest unoccupied molecular orbital 36 of the electron transport material, lowering of the electron transportability in the hole blocking layer 16 can be suppressed. As described above, also when the first light-emitting dopant and the third light-emitting dopant are formed of an identical material with that of the second light-emitting dopant or the fourth light-emitting dopant, lowering of the carrier transportability of the electron blocking layer 14 and the hole blocking layer 16 can be suppressed. Also in the configuration in which the three emission layers are stacked as shown in FIG. 7, localization of the excited state can be reduced.

FIG. 7 shows a conceptional view of an energy level in the organic light-emitting device.

In FIG. 7, a first organic multi-layers 105 comprises an electron blocking layer 14, a first emission layer 21, a second emission layer 22, a third emission layer 23, and a hole blocking layer 16. In the first emission layer 21, a second light-emitting dopant is added to a host material. In the second emission layer 22, a fourth light-emitting dopant is added to a host material. In the third emission layer 23, a fifth light-emitting dopant is added to a host material. The third light emission layer 23 is formed between the first emission layer 21 and the second emission layer 22. The electron blocking layer 14 is in contact with the first emission layer 21 on the side where the second emission layer 22 is not present, and the hole blocking layer 16 is in contact with the second emission layer 22 on the side where the first emission layer 21 is not present.

In FIG. 7, a wavelength where the emission intensity of the second light-emitting dopant is at the maximum, a wavelength where the emission intensity of the fourth light-emitting dopant is at the maximum, and the wavelength where the emission intensity of the fifth light-emitting dopant is at the maximum may be different from each other. A color for a wavelength where the emission intensity of the second light-emitting dopant is at the maximum, a color for a wavelength where the emission intensity of the fourth light-emitting dopant is at the maximum, and a color for a wavelength where the emission intensity of the fifth light-emitting dopant is at the maximum may be different from each other. For example, dopants having emission colors of red, green, and blue are added to the first emission layer 21, the third emission layer 23, the second emission layer 22 in this order. Thus, a white spectrum is obtained.

Further, it is preferred that the first light-emitting dopant and the third light-emitting dopant are the second light-emitting dopant, the fourth light-emitting dopant, or the fifth light-emitting dopant. In FIG. 7, the first light-emitting dopant equals the fifth light-emitting dopant and the third-emitting dopant equals the fifth light-emitting dopant. Since, in the first emission layer 21, the lowest unoccupied molecular orbital 72 of the first light-emitting dopant is shallower than the lowest unoccupied molecular orbital 20 of the hole transport material, electrons penetrating the first emission layer 21 are trapped at the first light-emitting dopant in the electron blocking layer 14, so that recombination occurs and light is emitted. Further, holes penetrating the first emission layer 21 are trapped at the fifth light-emitting dopant in the third emission layer 23, so that recombination occurs and light is emitted.

Then, in the second emission layer 22, holes penetrating the third emission layer 23 are trapped at the fourth light-emitting dopant in the second emission layer 22, so that recombination occurs and light is emitted. Further, electrons penetrating the third emission layer 23 are trapped at the second light-emitting dopant in the first emission layer 21, so that recombination occurs and light is emitted.

Then, since, in the second emission layer 22, the highest occupied molecular orbital 79 of the third light-emitting dopant is shallower than the highest occupied molecular orbital 18 of the electron transport material, holes penetrating the second emission layer 22 are trapped at the third light-emitting dopant in the hole blocking layer 16, so that recombination occurs and light is emitted. Further, electrons penetrating the second emission layer 22 are trapped at the fifth light-emitting dopant in the third emission layer 23, so that recombination occurs and light is emitted.

As described above, light is emitted in the first emission layer 21, the second emission layer 22, the third emission layer 23, the electron blocking layer 14, or the hole blocking layer 16, thereby achieving high efficiency light emission. In the configuration of FIG. 7, since the highest occupied molecular orbital 71 of the first light-emitting dopant is deeper than the highest occupied molecular orbital 33 of the hole transport material, lowering of the hole transportability in the electron blocking layer 14 can be suppressed. Further, since the lowest unoccupied molecular orbital 80 of the third light-emitting dopant is shallower than the lowest unoccupied molecular orbital 36 of the electron transport material, lowering of the electron transportability in the hole blocking layer 16 can be suppressed. As described above, also when the first light-emitting dopant and the third light-emitting dopant are formed of a material identical with that of the second light-emitting dopant, the fourth light-emitting dopant, or the fifth light-emitting dopant, lowering of the carrier transportability of the electron blocking layer 14 and the hole blocking layer 16 can be suppressed.

### <Emission Layer>

The emission layer 15 is a layer in which electrons and holes injected from electrodes, etc. are recombined and light emission takes place. The emitting portion may be within a layer of the emission layer 15 or may be at the boundary between the emission layer 15 and a layer adjacent with the emission layer 15. The emission layer 15 comprises the host material for the emission layer 15 and the second light-emitting dopant.

The emission layer 15 may consist of the host material for the emission layer 15 and the second light-emitting dopant, but an electron transport material, a hole transport material, etc. may be used together.

The host material for the emission layer 15 is a material used to fix the second light-emitting dopant. While UGH2 (A-1) is preferable since the difference between the HOMO level and the LUMO level, that is, a band gap is relatively broader than other host materials, the layer is not restricted to such material. Further, one or more of materials that can be used together may also be contained in the emission layer 15.

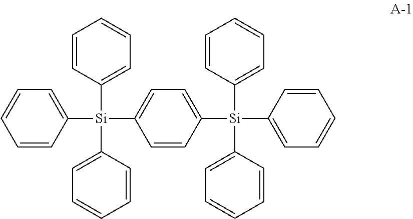 [SMILES: c1ccc([Si](c2ccccc2)(c2ccccc2)c2ccc([Si](c3ccccc3)(c3ccccc3)c3ccccc3)cc2)cc1]

The second light-emitting dopant is a material to be doped in the host material for the emission layer 15. As a blue phosphorescent material, FIr6 (A-2), FIrpic (A-3), etc. are preferable in terms of a high quantum yield, but the dopant is not restricted to such materials. As a red phosphorescent material, Ir(2-phq)2acac, Ir(piq)3, etc. are preferable in terms of a high quantum yield but the dopant is not restricted to such materials. As a green phosphorescent material, Ir(-ppy)2acac, Ir(ppy)3, etc. are preferable in terms of a high quantum yield, but the dopant is not restricted to such materials. Further, one or more of materials that can be used together may be contained in the emission layer.

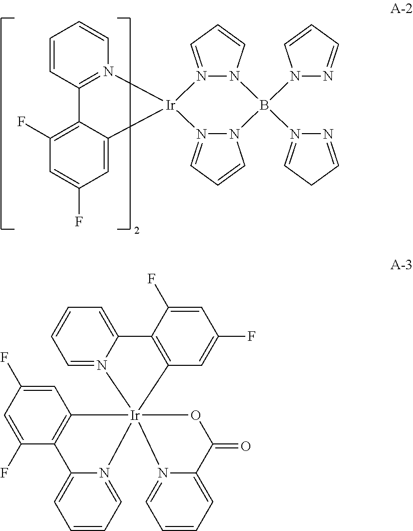

The blue phosphorescent material is a material having a blue light component that has a maximal emission wavelength in a region of 495 nm or less. The green phosphorescent material is a material that has a blue light component having a maximal emission wavelength in a region ranging from 495 to 570 nm. The red phosphorescent material is a material having a blue light component that has a maximal emission wavelength in a region ranging from 620 to 750 nm.

The emission layer 15 is prepared from a host material for the emission layer 15 and the second light-emitting dopant described above into a film by a known method such as a spin coating method, a casting method, an LB method, a spray method, an inkjet method, a paint method or the like.

### <Electron Blocking Layer>

The electron blocking layer 14 is a layer having a function of blocking electrons from the emission layer. The electron blocking layer 14 comprises a hole transport material and a third light-emitting dopant. The electron blocking layer may consist of the hole transport material and the third light-emitting dopant, but an electron transporting material or the like may be used together.

As the hole transport material, TAPC (A-4) and NPB (A-5) are preferable in that the LUMO level is shallow, but the materials are not restrictive. Further, one or more of the materials described above that can be used together may also be incorporated in the electron blocking layer.

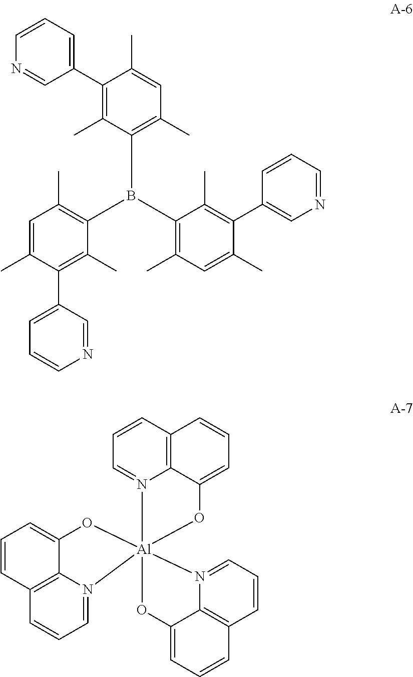

The third light-emitting dopant is a material to be doped in the electron blocking layer 14. While FIr6, FIrpic, Ir(2-phq)2acac, Ir(piq)3, Ir(ppy)2acac, and Ir(ppy)3 are preferable in terms of high quantum efficiency, but the dopant is not restricted to such materials. Further, one or more materials described above that can be used together may also be incorporated in the electron blocking layer 14.

### <Hole Blocking Layer>

The hole blocking layer 16 is a layer having a function of blocking holes from the emission layer 15. The hole blocking layer 16 comprises an electron transport material and a first light-emitting dopant. The hole blocking layer 16 may consist of the hole transport material and the first light-emitting dopant, but an electron transport material, etc. may also be used together.

As the electron transport material, 3TPYMB (A-6) and Alq₃ (A-7) are preferable in that the HOMO level is deep but the materials are not restrictive. Further one or more of the materials described above that can be used together may also be incorporated in the hole blocking layer.

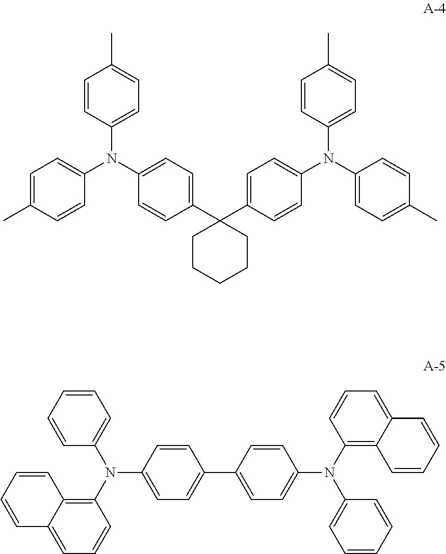

The first light-emitting dopant is a material to be doped in the hole blocking layer 16. FIr6, FIrpic, Ir(2-phq)2acac, Ir(piq)3, Ir(ppy)2acac, and Ir(ppy)3 are preferable in terms of high quantum efficiency, but the materials are not restrictive. Further, one or more of the materials described above that can be used together may also be incorporated in the hole blocking layer 16.

### <Substrate>

The first substrate 101 and second substrate 102 include, for example, glass substrates, metal substrates, and plastic substrates formed with inorganic materials such as SiO₂, SiNₓ, Al₂O₃, etc. The metal substrate materials include alloy such as stainless steel and alloys. The plastic substrate materials include, for example, polyethylene terephthalate, polyethylene naphthalate, polymethyl methacrylate, polysulfone, polycarbonate, and polyimide.

### <Hole Injection Layer>

The hole injection layer is used with an aim of improving an emission efficiency and life. Further, it is used with an aim of moderating unevenness of the anode although this is not always indispensable. The hole injection layer 1 may be disposed as a mono-layer or plural layers. For the hole injection layer 1, conductive polymers such as PEDOT (poly(3,4-ethylenedioxythiophene)); PSS (polystyrene sulfonate), etc. are preferable. In addition, polypyrrole and triphenylamine polymer materials may also be used. Further, phthalocyanine compounds or starburst amine compounds used frequently in combination with a low molecular material (weight average molecular weight of 10,000 or less) may also be applied.

### <Hole Transport Layer>

The hole transport layer comprises a material having a function of transporting holes and, in a broad sense, hole injection layer and an electron inhibition layer are also includes in the hole transport layer. The hole transport layer may be disposed as mono-layer or plural layers. For the hole transport layer, starburst amine compounds, stilbene derivatives, hydrazone derivatives, thiophene derivatives, etc. can be used. The materials are not restrictive, or two or more of such materials may also be used together.

### <Election Transport Layer>

The electron transport layer is a layer that supplies electrons to the emission layer. An electron injection layer and a hole inhibition layer are also included, in a broad sense, in the electron transport layer. The electron transport layer may be disposed as a mono-layer or plural layers. As the material of the electron transport material, for example, bis(2-methyl-8-quinolinolato)-4-(phenylphenolato)aluminum (hereinafter referred to as BAlq) or tris(8-quinolinolato)aluminum (hereinafter referred to as Alq₃), Tris(2,4,6-trimethyl-3-(pyridin-3-yl)phenyl)borane (hereinafter referred to as 3TPYMB), 1,4-bis(triphenylsilyl)benzene (hereinafter referred to as UGH2), oxadiazole derivatives, triazole derivatives, fullerene derivatives, phenanthroline derivatives, quinoline derivatives, etc. can be used.

### <Electron Injection Layer>

The electron injection layer improves the electron injection efficiency of from the cathode to the electron transport layer. Specifically, lithium fluoride, magnesium fluoride, calcium fluoride, strontium fluoride, barium fluoride, magnesium oxide, and aluminum oxide are preferable. The materials are not restrictive and two or more of such materials may be used together.

### <Anode>

For the anode material, any material having transparency and high work function can be used. Specifically, the anode material includes conductive oxides such as ITO and IZO, and metals having large work function such as thin Ag. Patterning of the electrode can be generally performed on a substrate such as glass by using, for example, photolithography.

### <Cathode>

A cathode material is a reflection electrode for reflecting light from the emission layer. Specifically, a laminate of LIF and Al, MgAg alloy, etc. are used preferably. Further, the materials are not restrictive and, for example, Cs compound, Ba compound, Ca compound, etc can be used instead of LiF.

### <Charge Generation Layer>

The charge generation layer is a layer of keeping the inside of the charge generation layer at an equi-potential state. Transparent conductive, films such as ITO, inorganic oxide such as V₂O₅, MoO₃, WO₃, etc., and metal films with a film thickness of 10 nm or less are preferable since they have free carriers but the material are not restrictive.

The content of the present invention will be described more in details while specific examples are shown.

### Example 1

### Preparation of Organic Light-Emitting Device

An organic light-emitting device OLED1 was manufactured as below.

OLED is an abbreviation of Organic Light-emitting device.

First, a glass substrate attached with an ITO (150 nm) electrode was dipped in acetone and subjected to supersonic cleaning for 10 minutes. Then, cleaning with pure water and rotational drying were performed by using a supersonic spin cleaner using pure water. Subsequently, the substrate was heated by using a hot plate in an atmosphere at 200° C. for 10 minutes. After the heating, the substrate was cooled for 10 minutes and an UV/O₃ treatment was performed at an irradiation intensity of 8 mW/cm² for 30 minutes.

An α-NPD was formed as a hole injection layer on the substrate applied with such treatments by a vacuum vapor deposition apparatus. The thickness of the hole injection layer was 5 nm.

Then, TAPC was formed as a hole transport layer over the substrate. The thickness of the hole injection layer was 85 nm.

Then, a layer in which mCP was doped with FIr6 (1 wt %) was formed as an electron blocking layer over the hole transport layer. The doping concentration was set to 1 wt %, because it was considered that when the doping concentration to the transport layer is high, it strongly functions as a trap level for the holes to remarkably lower the hole mobility in mCP. The thickness of the electron blocking layer was 10 nm.

Then, a layer in which UGH2 was doped with FIr6 (20 wt %) was formed as an emission layer over the electron blocking layer. The thickness of the emission layer was 20 nm.

Then, a layer in which 3TPYMB was doped with FIr6 (1 wt %) was formed as a hole blocking layer over the emission layer. The thickness of the hole blocking layer was 30 nm.

Then, LiF was formed as an electron injection layer over the hole blocking layer. The thickness of the electron injection layer was 0.5 nm.

Then, Al was vapor deposited as a cathode over the electron injection layer. The thickness of the cathode was 150 nm.

Finally, sealing was performed using a sealing can having a sealant to manufacture an organic light-emitting device OLED1.

An organic light-emitting device (organic light-emitting device OLED2) was manufactured by using the same steps as in the organic light-emitting device OLED1 except for not doping the electron blocking layer with a light-emitting dopant for the organic light-emitting device OLED1. Further, an organic light-emitting device (organic light-emitting device OLED3) was manufactured by using the same steps as in the organic light-emitting device OLED1 except for not doping the electron blocking layer and the hole blocking layer with the light-emitting dopant.

### Evaluation for Organic Light-Emitting Device

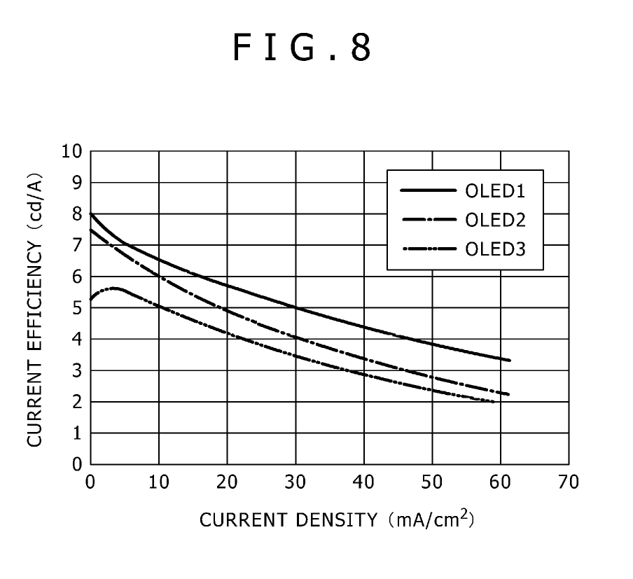

The organic light-emitting devices OLED1 to OLED3 were evaluated. A voltage was applied to the organic light-emitting devices OLED1 to OLED3 by using a digital source meter (4040B manufactured by HP Co.), and the current was measured by the meter and the luminance was measured by a luminance meter (LS-110 manufactured by Konica-Minolta. Co.). The current efficiency was calculated by dividing the measured luminance by a current density. The results are shown in FIG. 8.

As apparent from FIG. 8, the organic light-emitting device of the invention has good current efficiency and, particularly, reduction of the current efficiency along with increase in the current density can be suppressed further compared with other devices.

### Example 2

### Manufacture of Organic Light-Emitting Device

First, the thickness of ITO of a glass substrate attached with an ITO electrode was set to 110 nm. The method of cleaning the glass substrate attached with the electrode is identical with the method shown in Example 1.

NPB was formed as a hole injection layer over the substrate applied with a cleaning treatment. The thickness of the hole injection layer was 15 nm.

Then, TAPC was formed as the hole transport layer. The thickness of the hole transport layer was 44 nm.

Then, a layer in which CBP was doped with Ir(ppy)₃ (20 wt %) and Ir(piq)₂(acac) (3 wt %) was formed as a red emission layer over the hole transport layer. The thickness of the red emission layer was 20 nm.

Then, a layer in which CBP was doped with Ir(ppy)₃ (10 wt %) and Ir(piq)₂(acac) (0.25 wt %) was formed as a green emission layer over the red emission layer. The thickness of the green emission layer was 20 nm.

Then, CBP was formed as a hole blocking layer over the green emission layer. The thickness of the hole blocking layer was 25 nm.

Then, Alq₃ was formed as an electron transport layer over the hole blocking layer. The thickness of the electron transport layer was 40 nm.

Then, a layer comprising a layer in which Alq₃ was doped with Li at a 1:1 molar ratio and a layer comprising V₂O₅ were formed as a charge generation layer over the electron transport layer. The thickness of the film comprising Alq₃ and Li was 5 nm and the thickness of the layer comprising V₂O₅ was 0.5 nm.

Then, NPB was formed as a hole transport layer over the charge generation layer. The thickness of the hole transport layer was 15 nm.

Then, TAPC Was formed as a hole transport layer over the hole transport layer. The thickness of the hole transport layer was 8 nm.

Then, a layer in which Ir(ppy)₃ (20 wt %) and Ir (piq)₂(acac) (3 wt %) were doped to CBP was formed as a red green emission layer over the hold transport layer. The thickness of the red green emission layer was 20 nm.

Then, a layer in which CBP was doped with Ir(ppy)₃ (10 wt %) and Ir(piq)₂(acac) (0.25 wt %) was formed as a red green emission layer over the red green emission layer. The thickness of the red green emission layer was 20 nm.

Then, CBP was formed as a hole blocking layer over the red green emission layer. The thickness of the hole blocking layer was 20 nm.

Then, Alq₃ was formed as an electron transport layer over the hole blocking layer. The thickness of the electron transport layer was 40 nm.

Then, a layer in which Alq₃ was doped with Li at a 1:1 molar ratio and a layer comprising V₂O₅ were formed as a charge generation layer, over the electron transport layer. The thickness of the layer comprising Alq₃ and Li was 5 nm and the thickness of the layer comprising V₂O₅ was 5 nm.

Then, NPB was formed as a hole transport layer over the charge generation layer. The thickness of the hole transport layer was 50 nm.

Then, TAPC was formed as a hole transport layer over the hole transport layer. The thickness of the hole transport layer was 45 nm.

Then, a layer in which mCP was honed with FIr6 (1 wt %) was formed as an electron blocking layer over the hole transport layer. The thickness of the electron blocking layer was 10 nm.

Then, a layer in which UGH2 was doped with FIr6 (20 wt %) was formed as an emission layer over the electron blocking layer. The thickness of the emission layer was 20 nm.

Then, a layer in which 3TPYMB was doped with FIr6 (1 wt %) was formed as a hole blocking layer over the emission layer. The thickness of the hole blocking layer was 30 nm.

Then, LiF was formed as an electron injection layer over the hole blocking layer. The thickness of the electron injection layer was 0.5 nm.

Then, Al was formed as a cathode over the electron injection layer. The thickness of the cathode was 150 nm.

Finally, sealing was performed using a sealing can with a sealant, to manufacture an organic light-emitting device OLED4.

An organic light-emitting device (organic light-emitting device OLED5) was manufactured by using the same steps as those for the organic light-emitting device OLED4 except for not doping the electron blocking layer of the blue emission unit with the light-emitting dopant for the organic light-emitting device OLED4. Further, an organic light-emitting device (organic light-emitting device OLED6) was manufactured by using the same step as those for the organic light-emitting device OLED4 except for not doping the electron blocking layer and the hole blocking layer with the light-emitting dopant.

### Evaluation of Organic Light-Emitting Device

The organic light-emitting devices OLED4 to OLED6 were evaluated. The evaluation method was identical with that in Example 1. As a result, OLED4 was most excellent in the current efficiency and, particularly, lowering of the current efficiency along with increase in the current density was suppressed further compared with other devices. Further, the dependence of the white chromaticity on the current density could be decreased remarkably in OLED4.

### DESCRIPTION OF REFERENCE NUMERALS

1, 2, 15: Emission layer
3: Highest occupied molecular orbital of hole transport layer 24
4: Highest occupied molecular orbital of a host material of emission layer 1
5: Highest occupied molecular orbital of a host material of emission layer 2
6: Lowest unoccupied molecular orbital of electron transport layer 26
7: Lowest unoccupied molecular orbital of host material of emission layer 1
8: Lowest unoccupied molecular orbital of host material of emission layer 2
9: Hole
10: Electron
11: Lowest unoccupied molecular orbital of light-emitting dopant of emission layer 1 (emission layer 2)
12: Highest occupied molecular orbital of light-emitting dopant of emission layer 1 (emission layer 2)
13: Recombination region
14: Electron blocking layer
16: Hole blocking layer
17: Highest occupied molecular orbital of host material of emission layer 15
18: Highest occupied molecular orbital of electron transport material
19: Lowest unoccupied molecular orbital of host material of emission layer 15
20: Lowest unoccupied molecular orbital of hole transport material
21: First emission layer
22: Second emission layer
23: Third emission layer
24: Hole transport layer
26: Electron transport layer
31, 62, 72: Lowest unoccupied molecular orbital of first light-emitting dopant
32, 67, 79: Highest occupied molecular orbital of third light-emitting dopant
33: Highest occupied molecular orbital of hole transport material
34: Lowest unoccupied molecular orbital of second light-emitting dopant
35: Highest occupied molecular orbital of a second light-emitting dopant
36: Lowest unoccupied molecular orbital of electron transport material
41, 61, 71: Highest occupied molecular orbital of first light-emitting dopant
42, 68, 80: Lowest unoccupied molecular orbital of a third light-emitting dopant
101: First substrate
102: Second substrate
103: First electrode
104: Second electrode
105: First organic multi-layers
106: First charge generation layer
115: Second organic multi-layers
116: Second charge generation layer
125: Third organic multi-layers

1. An organic light-emitting device comprising:
a first electrode;
a second electrode;
organic multi-layers formed between the first electrode and the second electrode;
the organic multi-layers having a hole blocking layer, an emission layer, and an electron blocking layer; and
the emission layer being interposed between the hole blocking layer and the electron blocking layer;
wherein a first light-emitting dopant is added to the hole blocking layer,
a second light-emitting dopant is added to the emission layer,
a third light-emitting dopant is added to the electron blocking layer, and
the first light-emitting dopant and the third light-emitting dopant trap carriers that inject to the emission layer.

2. An organic light-emitting device according to claim 1, wherein
an electron transport material is added to the hole blocking layer, and a hole transport material is added to the electron blocking layer, and the following relations (1) and (2) are satisfied when assuming the energy of the lowest occupied molecular orbital of the hole transport material as LUMO (EBL_host), the energy of the lowest occupied molecular orbital of the first light-emitting dopant as LUMO (EBL_dop), the energy of the highest occupied molecular orbital of the electron transport material as HOMO (HBL_host), and the energy of the highest occupied molecular orbital of the third light-emitting dopant as HOMO (HBL_dop):
LUMO(EBL_host)≦LUMO(EBL_dop) (1)
HOMO(HBL_host)≧HOMO(HBL_dop) (2)

3. An organic light-emitting device according to claim 1, wherein
the following relations (3) and (4) are satisfied when assuming the lowest triplet energy state of the first light-emitting dopant as T_{1EBL-D}, the lowest triplet energy state of the second light-emitting dopant as T_{1EML-D}, and the lowest triplet energy state of the third light-emitting dopant as T_{1HBL-D}:
T_{1EML}_{_{—}}_{D}≦T_{1EBL}_{_{—}}_{D} (3)
T_{1EML}_{_{—}}_{D}≦T_{1HBL}_{_{—}}_{D} (4)

4. An organic light-emitting device according to claim 1, wherein the following relation (5) is satisfied when assuming the hole mobility in the emission layer as μ_{h-EML} and the electron mobility in the emission layer as μ_{e-EML}:
0.7μₕ_{_{—}}_{EML}≧μₑ_{_{—}}_{EML}≧1.3μₕ_{_{—}}_{EML} (5)

5. An organic light-emitting device according to claim 1, wherein
the following relation (6) and (7) are satisfied when assuming an energy barrier at the boundary between the hole blocking layer and the emission layer as φₕ and an energy barrier at the boundary between the emission layer and the electron blocking layer as φₑ:
Φₕ≦0.3eV (6)
Φₑ≦0.3eV (7)

6. An organic light-emitting device according to claim 1, wherein
the emission color of the first light-emitting dopant, the emission color of the second light-emitting dopant, and the emission color of the third light-emitting dopant are identical.

7. An organic light-emitting device according to claim 1, wherein
the following relations (8) and (9) are satisfied when assuming the dopant concentration of the first light-emitting dopant in the hole blocking layer as D₁, the dopant concentration of the second light-emitting dopant in the emission layer as D₂, and the dopant concentration of the third light-emitting dopant in the electron blocking layer as D₃:
D₁≦0.1D₂ (8)
D₃≦0.1D₂ (9)

8. An organic light-emitting device according to claim 1, wherein
the first light-emitting dopant, the second light-emitting dopant, and the third light-emitting dopant are blue phosphorescent materials.

9. An organic light-emitting device according to claim 8, wherein
the blue phosphorescent material is FIr6 or FIrpic.

10. An organic light-emitting device comprising:
a first electrode;
a second electrode;
organic multi-layers formed between the first electrode and the second electrode;
the organic multi-layers having a hole blocking layer, a first emission layer, a second emission layer, and an electron blocking layer; and
the first emission layer and the second emission layer being stacked and interposed between the hole blocking layer and the electron blocking layer;
wherein a first light-emitting dopant is added to the hole blocking layer,
a second light-emitting dopant is added to the first emission layer,
a third light-emitting dopant is added to the electron blocking layer,
a fourth light-emitting dopant is added to the second emission layer,
the first light-emitting dopant traps electrons that inject to the first emission layer, and
the third light-emitting dopant traps holes that inject to the second emission layer.

11. An organic light-emitting device according to claim 10, wherein
the first light-emitting dopant is formed of a material identical with that of the second light-emitting dopant or the fourth light-emitting dopant, and the third light-emitting dopant is formed of a material identical with that of the second light-emitting dopant or the fourth light-emitting dopant.

12. An organic light-emitting device according to claim 10, wherein
a third emission layer is formed between the first emission layer and the second emission layer, and a fifth light-emitting dopant is added to the third emission layer, whereby white light is emitted.

13. A light source system including the organic light-emitting device according to claim 1 and a driving device.

14. An organic light-emitting device comprising:
a first electrode;
a second electrode;
organic multi-layers;
a charge generation layer;
the organic multi-layers and the charge generation layer being stacked alternately between the first electrode and the second electrode;
the first electrode and the second electrode being in contact with the organic multi-layers;
the organic multi-layers having at least a hole blocking layer, an emission layer, and an electron blocking layer; and
the emission layer being stacked in plurality and interposed between the hole blocking layer and the electron blocking layer;
wherein a light-emitting dopant is added to the hole blocking layer, the emission layer, and the electron blocking layer, and the light-emitting dopant traps carriers that inject to the emission layer.
